(19) United States
(12) Patent Application Publication
(10) Pub. No.: US 2025/0014667 A1
(43) Pub. Date: Jan. 9, 2025

(54) MEMORY CIRCUIT

(71) Applicant: ROHM CO., LTD., Kyoto-shi (JP)

(72) Inventor: Daigo FUJIMURA, Kyoto-shi (JP)

(21) Appl. No.: 18/894,510

(22) Filed: Sep. 24, 2024

Related U.S. Application Data
(63) Continuation of application No. PCT/JP2023/011788, filed on Mar. 24, 2023.

(30) Foreign Application Priority Data
Mar. 31, 2022 (JP) 2022-060049

(51) Int. Cl. G11C 29/46; G11C 29/12

(52) U.S. Cl. CPC G11C 29/46; G11C 29/1201; G11C 2029/1204

(57) ABSTRACT

A memory circuit includes a first switch provided for each pair of first and second bit lines and connected to a first and a second memory cell, a first all bit line selection circuit that, if an input test signal indicates a test, can turn on all the first switches regardless of the bit data of an input switch control signal, and a sensing circuit that can sense the magnitude relationship between the sum of currents flowing through the first bit lines and a reference current and the magnitude relationship between the sum of currents flowing through the second bit lines and the reference current. The gate of a first memory transistor and the gate of a second memory transistor can be fed with a direct-current voltage.

### CROSS-REFERENCE TO RELATED APPLICATIONS

This application is a continuation under 35 U.S.C. § 120 of PCT/JP2023/011788 filed on Mar. 24, 2023, which is incorporated herein by reference, and which claimed priority to Japanese Patent Application No. 2022-060049 filed on Mar. 31, 2022. The present application likewise claims priority under 35 U.S.C. § 119 to Japanese Application No. 2022-060049, filed Mar. 31, 2022, the entire content of which is also incorporated herein by reference.

### TECHNICAL FIELD

The present disclosure relates to a memory circuit.

### BACKGROUND ART

Some known semiconductor memory devices include a memory cell. The memory cell includes a memory transistor. One type of memory transistor, for example, has a control gate and a floating gate, and a high voltage is applied to an oxide film arranged adjacent to the floating gate to inject and extract electrons from the floating gate to perform deleting (erasing) and writing (programming). (see, for example, Patent Document 1).

### CITATION LIST

### Patent Literature

Patent Document 1: Japanese Unexamined Patent Application Publication No. 2017-174485

### BRIEF DESCRIPTION OF DRAWINGS

FIG. 1 is a diagram showing the configuration of a memory cell.

FIG. 2 is a diagram showing the vertical structure of a memory transistor.

FIG. 3A is a diagram showing a memory cell including a memory transistor in a program state (a write state).

FIG. 3B is a diagram showing a memory cell including a memory transistor in an erase state (a delete state).

FIG. 4 is a diagram showing the relationship between the gate voltage and the drain current in the program state and the erase state.

FIG. 5 is a diagram showing a complementary cell.

FIG. 6 shows data states (storage states) of a complementary cell and the gate voltage Vcg-drain current Id characteristics corresponding to those data states.

FIG. 7 is a schematic diagram showing the configuration of an IC chip having a memory circuit according to a comparative example.

FIG. 8 is a diagram showing the gate voltage Veg-drain current Id characteristics of a memory transistor.

FIG. 9 is a schematic diagram showing an IC chip having a memory circuit according to a first embodiment of the present disclosure.

FIG. 10 shows the relationship, plotted against frequency, of the threshold voltage of memory transistors in the erase state.

FIG. 11 shows the gate voltage Vcg-drain current Id characteristics of a memory transistor.

FIG. 12 is a schematic diagram showing the configuration of an IC chip having a memory circuit according to a second embodiment of the present disclosure.

### DESCRIPTION OF EMBODIMENTS

Hereinafter, an illustrative embodiment of the present disclosure will be described with reference to the drawings.

### <1. Complementary Cell>

FIG. 1 is a diagram showing the configuration of a memory cell MC. The memory cell MC has a memory transistor MT and a selection transistor ST. The memory transistor MT is configured as an NMOS transistor (N-channel MOSFET [metal-oxide-semiconductor field-effect transistor]) and is an element for storing data. The memory transistor MT has a control gate Cg and a floating gate Fg.

The selection transistor ST is configured as an NMOS transistor and is an element for selecting the memory transistor MT. The source of the memory transistor MT is connected to an application terminal for a ground potential. The drain of the memory transistor MT is connected to the source of the selection transistor ST. The drain of the selection transistor ST is connected to a bit line BL. The selection transistor ST has a read gate Rg. According to a voltage fed to the read gate Rg, the selection transistor ST is turned on and off.

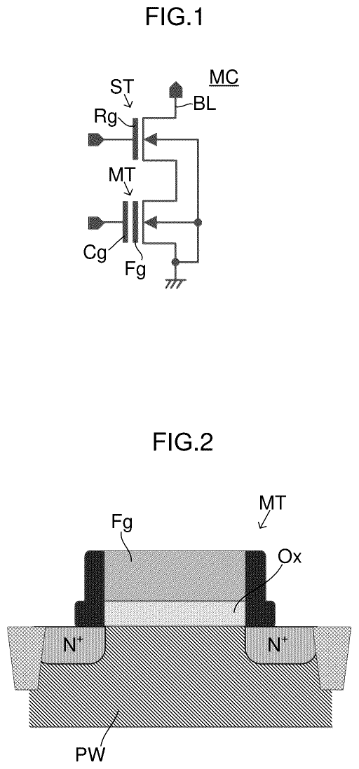

FIG. 2 is a diagram showing the vertical structure of the memory transistor MT. As shown in FIG. 2, a P-well region PW is formed in a semiconductor substrate. In the surface of the P-well region PW, two N⁺ regions are formed. Immediately above a channel region between the two N⁺ regions, an oxide film Ox is formed. Immediately above the oxide film Ox, the floating gate Fg is formed. Immediately above the floating gate Fg, a control gate Cg, which is not illustrated, is arranged.

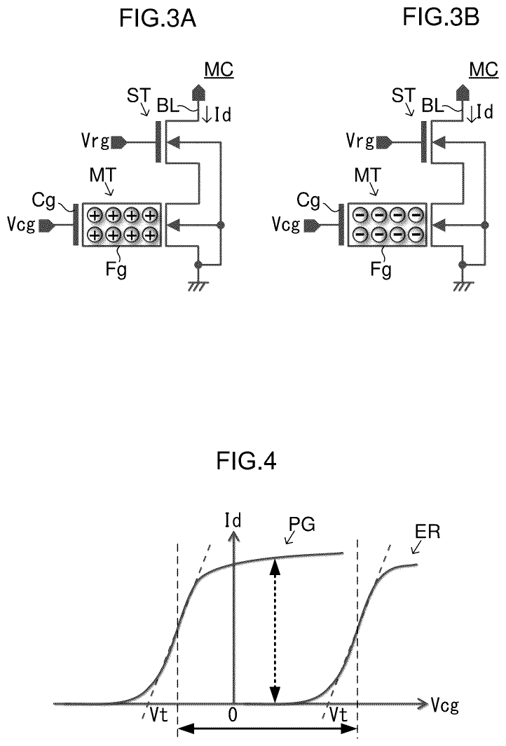

FIG. 3A is a diagram showing the memory cell MC including the memory transistor MT in a program state (a write state). When a positive potential is applied to a program gate, which is not illustrated, electrons are attracted toward a back gate and holes are repelled toward the floating gate. Here, if a negative gate voltage Vcg is applied to the control gate Cg, then, as shown in FIG. 3A, holes are attracted to the floating gate Fg and the floating gate Fg enters a hole-rich state. This state is the program state.

By contrast, FIG. 3B is a diagram showing the memory cell MC including the memory transistor MT in an erase state (a delete state). When a negative potential is applied to an erase gate, which is not illustrated, holes are attracted toward the back gate and electrons are repelled toward the floating gate. Here, if a positive gate voltage Vcg is applied to the control gate Cg, then, as shown in FIG. 3B, electrons are injected into the floating gate Fg and the floating gate Fg enters an electron-rich state. This state is the erase state.

FIG. 4 is a diagram showing the relationship, as observed with the gate voltage Vrg fed to the read gate Rg such that the selection transistor ST is on, between the gate voltage Veg fed to the control gate Cg of the memory transistor MT in each of the program state PG and the erase state EG and the drain current Id flowing through the memory transistor MT. As shown in FIG. 4, in the program state PG, a threshold voltage Vt has a negative value and in the erase state ER, the threshold voltage Vis has a positive value.

With these characteristics in the program state and the erase state, when the reading gate voltage Veg is applied to the control gate Cg, the drain current Id varies in magnitude between the program state and the erase state. Thus, when with the selection transistor ST on the reading gate voltage Veg is applied to the control gate Cg, the drain current Id flows through the bit line BL and data can be read according to the magnitude of the drain current Id.

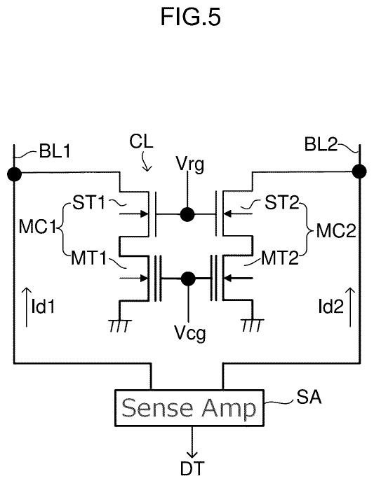

In the embodiment of the present disclosure, as shown in FIG. 5, two memory cells are arranged together to configure what is called a complementary memory cell (a complementary cell). A complementary cell CL has a first memory cell M1 and a second memory cell M2. The first memory cell MC 1 has a first selection transistor ST1 and a first memory transistor MT1. The second memory cell M2 has a second selection transistor ST2 and a second memory transistor MT2. The first selection transistor ST1 is connected to a first bit line BL1. The second selection transistor ST2 is connected to a second bit line BL2. The bit lines BL1 and BL2 are connected to a sense amplifier SA. When the gate voltage Vrg applied to the read gate is such that the selection transistors ST1 and ST2 are on and the reading gate voltage Veg is applied to the control gates of the memory transistors MT1 and MT2, the sense amplifier SA, senses the magnitude relationship between the first drain current Id1 flowing through the first memory cell MC1 and the second drain current Id2 flowing through the second memory cell MC2, and thereby reads one-bit data DT. The gate voltage Veg applied to the control gate is set within a region indicated by the solid line in FIG. 4 to produce a current difference indicated by the broken line in FIG. 4 between the erase state and the program state, and this achieves data determination.

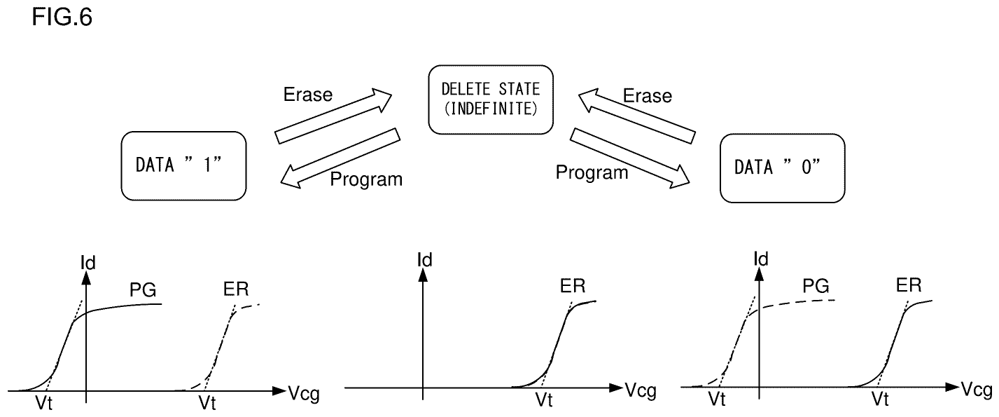

FIG. 6 shows the data states (storage states) of the complementary cell CL and the gate voltage Vcg-drain current Id characteristics corresponding to those data states. In FIG. 6, the solid line indicates the characteristics of the first memory transistor MT1 and the broken line indicates the second memory transistor MT2.

As shown in FIG. 6, if the memory transistors MT1 and MT2 are both in the erase state ER, the data DT read by the sense amplifier SA is indefinite and the complementary cell CL is in the delete state.

If the first memory transistor MT1 is in the program state and the second memory transistor MT2 is in the erase state ER, the first drain current Id1 is higher than the second drain current Id2 and thus the sense amplifier SA reads data DT=“1”. That is, the complementary cell CL stores data “1”.

If the second memory transistor MT2 is in the program state and the first memory transistor MT1 is in the erase state ER, the first drain current Id1 is lower than the second drain current Id2 and thus the sense amplifier SA reads data DT=“0”. That is, the complementary cell CL stores data “0”.

As shown in FIG. 6, depending on which of the memory transistors MT1 and MT2 is changed from the delete state to the program state, the complementary cell CL stores data “1” or “0”. In the storage state of data “1” or “0”, changing the memory transistor from the program state to the erase state brings the complementary cell CL into the delete state.

### 2. Comparative Example

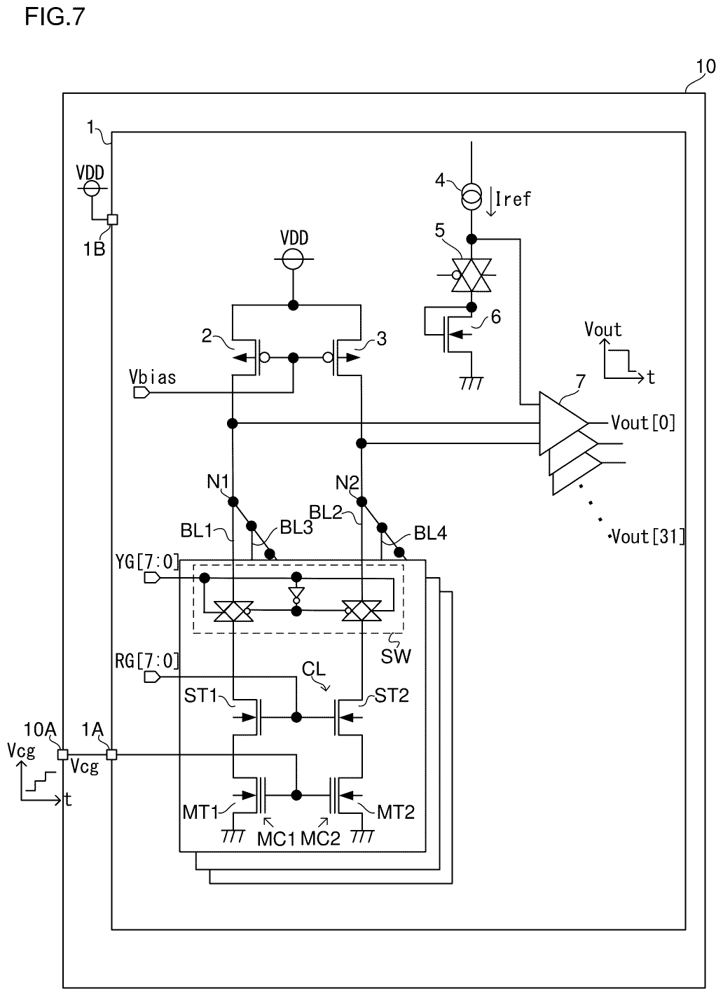

Next, a function to check the delete state in the complementary cell CL described above (a delete state checking function) will be described. First, a comparative example for comparison with the embodiment of the present disclosure will be described. FIG. 7 is a schematic diagram showing the configuration of an IC (integrated circuit) chip 10 having a memory circuit 1 according to the comparative example.

The memory circuit 1 corresponds to a memory function block (memory IP [intellectual property core]) in the IC chip 10. The memory circuit 1 has the complementary cell CL, a switch SW, PMOS transistors (P-channel MOSFETs) 2 and 3, a constant current source 4, a switch 5, an NMOS transistor 6, and an amplifier 7. The memory circuit 1 has terminals 1A and 1B for establishing electrical connection with the outside of the circuit. The terminal 1B can be fed with a supply voltage VDD necessary for the operation of the memory circuit 1. The supply voltage VDD is a direct-current voltage.

Although the circuits other than the memory circuit 1 in the IC chip 10 are not illustrated in FIG. 7, they can have any configurations. The IC chip 10 has an external terminal 10A for establishing electrical connection with the outside of the chip.

The complementary cell CL, as in the configuration described previously, has a first memory cell MC1 and a second memory cell MC2. The first memory cell MC 1 has a first selection transistor ST1 and a first memory transistor MT1. The second memory cell M2 has a second selection transistor ST2 and a second memory transistor MT2. The complementary cell CL can store data “1” or “0”.

The read gates of the selection transistors ST1 and ST2 can be fed with a read gate signal RG. According to the read gate signal RG, the selection transistors ST1 and ST2 are turned on and off. The control gates of the memory transistors MT1 and MT2 can be fed with the reading gate voltage Veg across a path not illustrated in FIG. 7.

The first and second selection transistors ST1 and ST2 are connected via the switch SW to the first and second bit lines BL1 and BL2 respectively. The switch SW is turned on and off by a switch control signal YG. A plurality of pairs of first and second bit lines are provided. For example, if there are eight pairs of bit lines, the pairs of bit lines (BL1, BL2), (BL3, BL4), . . . (BL15, BL16) are provided. The first bit lines BL1 etc. are connected together at a node N1. The second bit lines BL2 etc. are connected together at a node N2.

For each pair of bit lines, a complementary cell CL and a switch SW are provided. In FIG. 7, which shows an example with eight pairs of bit lines as mentioned above, eight complementary cells CL and eight switches SW are provided. Thus, as shown in FIG. 7, the read gate signal SG is eight-bit data (RG [7:0]) to control the selection transistors ST1 and ST2 in each of the eight complementary cells CL and the switch control signal is eight-bit data (YG [7:0]) to control each of the eight switches SW.

The plurality of pairs of bit lines are connected to common PMOS transistors 2 and 3. The first bit lines BL1 etc. are connected to the drain of the PMOS transistor 2. The second bit lines BL2 etc. are connected to the drain of the PMOS transistor 3. The sources of the PMOS transistors 2 and 3 are connected to an application terminal for the supply voltage VDD. The gates of the PMOS transistors 2 and 3 can be fed with a bias voltage Vbias. The bias voltage Vbias is a predetermined direct-current voltage.

To the bit lines BL1, BL2, etc., a reading sense amplifier not shown in FIG. 7 is connected. During reading by the sense amplifier, the switch control signal YG keeps one of the switches SW on while the read gate signal RG keeps one of the selection transistors ST1 and ST2 on.

The constant current source 4, the switch 5, the NMOS transistor 6, the amplifier 7, the terminal 1A and the external terminal 10A are provided for a function to check the delete state in the complementary cell CL.

The constant current source 4 is connected to the drain of the diode-connected NMOS transistor 6 via the switch 5. The drain of the NMOS transistor 6 is connected to a first input terminal of the amplifier 7. A voltage corresponding to a reference current Iref generated by the constant current voltage 4 appears at the drain of the NMOS transistor 6 and is fed to the first input terminal of the amplifier 7. When the delete state checking function is not operated, turning off the switch 5 can reduce unnecessary power consumption.

The control gates of the memory transistors MT1 and MT2 are both connected to the terminal 1A. The terminal 1A is connected to the external terminal 10A. The control gates of the memory transistors MT1 and MT2 can be fed with the gate voltage Vcg from the outside via the external terminal 10A. The gate voltage Veg may be fed for each of the plurality of pairs of memory transistors MT1 and MT2. The first bit lines BL1 etc. are connected to a second input terminal of the amplifier 7. The second bit lines BL2 etc. are connected to a third input terminal of the amplifier 7.

Turning on the PMOS transistors 2 and 3 with the bias voltage Vbias, permits pre-charging of the bit lines BL1, BL2, etc. (i.e., charging of the parasitic capacitances of the bit lines LB1, BL2, etc.). After the pre-charging of the bit lines BL1, BL2, etc., turning off the PMOS transistors 2 and 3 with the bias voltage Vbias, turning on one of the selection transistors ST1 and ST2 with the read gate signal RG, and turning on one of the switches SW with the switch control signal YG results in the parasitic capacitance of the bit lines BL1, BL2, etc. being discharged with the current flowing through the memory transistors MT1 and MT2.

The amplifier 7 can select one of the bit lines BL1 and BL2. Then, according to the time required for the voltage at the input terminal (the second or third input terminal) of the amplifier 7 corresponding to the selected bit line to fall, through the above discharging, down to the voltage at the first input terminal (the drain voltage of the NMOS transistor 6), the amplifier 7 outputs a logic output Vout (high level or low level). More specifically, if the time mentioned above is longer than a predetermined time, the logic output Vout remains at high level, and if the time mentioned above is equal to or shorter than the predetermined time, the logic output Vout switches from high level to low level. The predetermined time is a time required for a fall, through discharging with the reference current Iref, of the supply voltage VDD, which is the voltage at the bit lines BL1, BL2, etc. after pre-charging, down to the voltage at the first input terminal of the amplifier 7.

Thus, the amplifier 7 senses the magnitude relationship between the current flowing through the first bit line BL1 etc. and the reference current Iref or the magnitude relationship between the current flowing through the second bit line BL2 etc. and the reference current Iref. In the following description, if the current flowing through the bit lines BL1, BL2, etc. is lower than the reference voltage Iref, the logic output Vout is at high level, and if the current flowing through the bit lines BL1, BL2, etc. is equal to or higher than the reference voltage Iref, the logic output Vout is at low level.

As shown in FIG. 7, a plurality (32 in the example in FIG. 7) of amplifiers 7 are provided. For each amplifiers 7, the PMOS transistors 2 and 3, the first bit lines BL1 etc., the second bit lines BL2 etc., the switch SW, and the complementary cell CL are provided. The first input terminal of each of the amplifiers 7 is fed with the drain voltage of the NMOS transistor 6. Thus, as many logic outputs Vout (in the example in FIG. 7, Vout [0] to Vout [31]) as the number of the amplifiers 7 are generated.

Next, the operation of the delete state checking function by the memory circuit 1 with the above configuration will be described. To check the delete state in the complementary cell CL, it is necessary to check whether both the memory cells MC1 and MC2 are in the erase state. In the memory circuit 1, the erase state in the memory cells MC1 and MC2 is checked one by one. Before the erase state is checked, the bit lines BL1, BL2, etc. are pre-charged.

When checking the erase state in the first memory cell MC1, the selection transistors ST1 and ST2 in the complementary cell CL, which is the check target, are kept on with the read gate signal RG and the selection transistors ST1 and ST2 in the complementary cell CL, which is not the check target, are kept off with the read gate signal RG. Meanwhile, the switch SW corresponding to the complementary cell CL, which is the check target, is kept on by the switch control signal YG and the other switches SW are kept off. In that state, the external terminal 10A is fed with the gate voltage Veg from the outside.

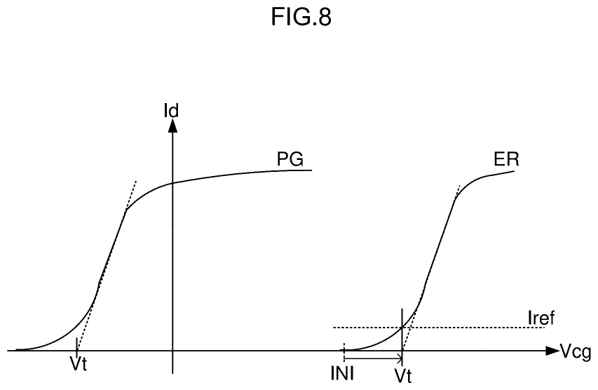

FIG. 8 shows the gate voltage Veg-drain current Id characteristics of the memory transistors MT1 and MT2. FIG. 8 shows the characteristics of the erase state ER and the program state PG in the memory transistors MT1 and MT2.

First, the gate voltage Veg with an initial value INI is applied. The initial value INI is a value between the threshold voltage Vt in the program state PG and the threshold voltage Vt in the erase state ER. When the gate voltage Veg with the initial value INI is applied and the current flowing through the first memory cell MC1 (the first bit line) is lower than the reference voltage Iref, the logic output Vout output from the amplifier 7 that has selected the first bit line is at high level; thus, it is sensed that the first memory cell MC1 is in the erase state. In this case, while the gate voltage Veg is increased stepwise in predetermined voltage increments, the logic output Vout output from the amplifier 7 is checked. Then, the gate voltage Veg is identified when the logic output Vout is switched from high level to low level, that is, when the current flowing through the first memory cell MC1 becomes equal to or higher than the reference current Iref, and thereby the threshold voltage Vt in the erase state ER is acquired.

As described above, in this comparative example, by applying the gate voltage Vcg that varies stepwise, it is possible to sense that the first memory transistor MT1 is in the erase state ER and to sense the threshold voltage Vt in the erase state ER. It is thus possible to sense the threshold voltage Vt corresponding to the variation of the characteristics of the first memory transistor MT1. When the initial value INI of the gate voltage Veg is applied, if the logic output Vout output from the amplifier 7 is at low level, it is sensed that the first memory transistor MT1 is in the program state PG.

A check for the erase state in the second memory cell MC2 is performed, as with the first memory cell MC1, by sensing the magnitude relationship between the current flowing through the second memory cell MC2 and the reference current Iref with the amplifier 7. When both the memory cells MC1 and MC2 are checked to be in the erase state, the delete state of the complementary cell CL is checked.

However, in this comparative example, the switch control signal YG can select only one switch SW and the read gate signal RG can select only one pair of selection transistors ST1 and ST2, so when the delete state of the complementary cell CL is checked, it is necessary to check one by one the memory transistor MT1 or MT2 connected to one bit line, and this inconveniently results in a long check time.

### 3. First Embodiment of the Present Disclosure

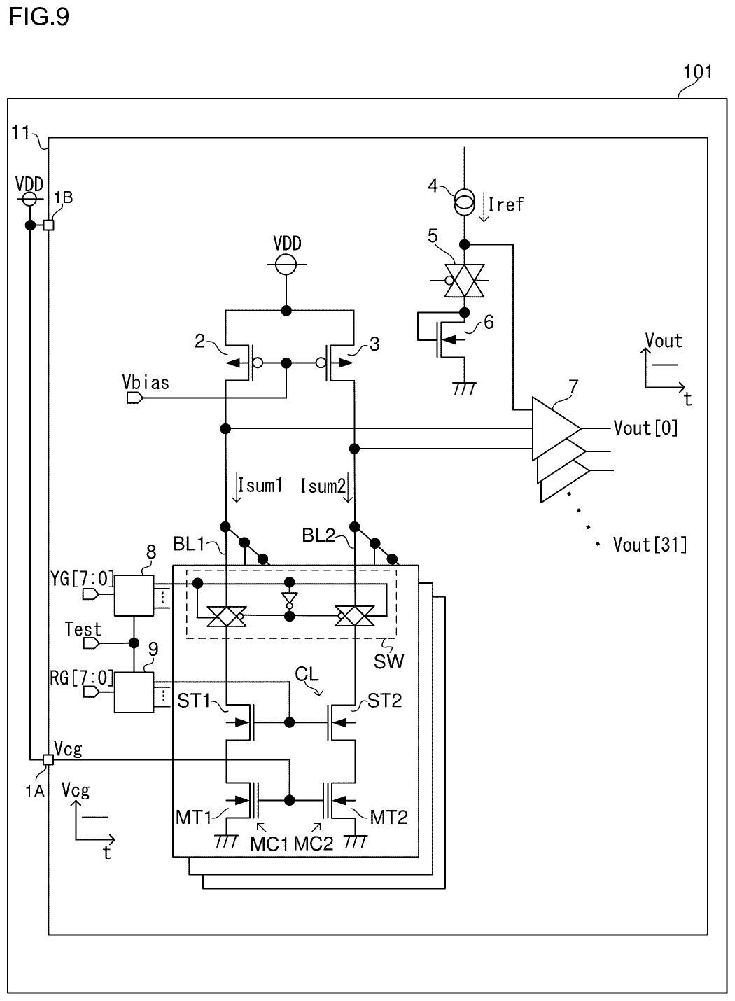

To solve the problem described above in the comparative example, an embodiment of the present disclosure is implemented as described below. FIG. 9 is a schematic diagram showing an IC chip 101 having a memory circuit 11 according to a first embodiment of the present disclosure.

The memory circuit 11 differs from the memory circuit 1 (see FIG. 7) according to the comparative example of in that it includes all bit line selection circuits 8 and 9. The all bit line selection circuits 8 and 9 are provided for each amplifier 7.

The all bit line selection circuit 8 is a circuit that, if a test signal Test indicates a delete check test, turns on all the switches SW regardless of the bit data of the switch control signal YG to select all the bit lines. If the test signal Test does not indicate a delete check test, the all bit line selection circuit 8 turns the switch SW on and off according to the bit data of the switch control signal YG.

The all bit line selection circuit 9 is a circuit that, if the test signal Test indicates a delete check test, turns on all the pairs of selection transistors ST1 and ST2 regardless of the bit data of the read gate signal RG to select all the bit lines. If the test signal Test does not indicate a delete check test, the all bit line selection circuit 9 turns the selection transistors ST1 and ST2 on and off according to the bit data of the read gate signal RG.

The terminals 1A and 1B are both connected to the application terminal for the supply voltage VDD. Thus, the IC chip 101 has no external terminal comparable with the external terminal 10A provided on the IC chip 10 according to the comparative example.

The operation for a check for the erase state in the complementary cell CL in the memory circuit 11 of this embodiment will be described. To check the delete state in the complementary cell CL, it is necessary to check whether both the memory cells MC1 and MC2 are in the erase state. In the memory circuit 1, the erase state in the memory cells MC1 and MC2 is checked one by one. Before the erase state is checked, the bit lines BL1, BL2, etc. are pre-charged.

In this embodiment, for the check for the erase state in the first memory cell MC1, the test signal Test is made to indicate a delete check test so that all the switches SW are turned on and that all the selection transistors ST1 and ST2 are turned on, and in addition the supply voltage VDD is fed as the gate voltage Veg to the control gates of the memory transistors MT1 and MT2 in all the complementary cells CL via the terminal 1A. In this state, the amplifier 7 selects the first bit lines BL1 etc.

Meanwhile, the amplifier 7 discharges the bit line BL1 with a current Isum1 that is the current flowing through the first bit lines BL1 etc., that is, the sum of the currents flowing through the first memory cell MC1 in all the complementary cell CL. The amplifier 7 senses the magnitude relationship between the current Isum1 and the reference current Iref and outputs the logic output Vout according to the sensing result.

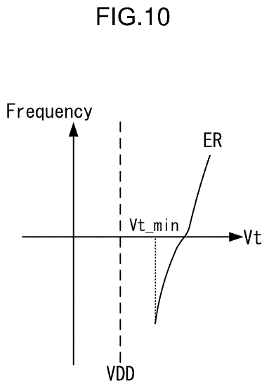

FIG. 10 shows, in a form plotted against frequency, the threshold voltage Vt of the memory transistors MT1 and MT2 in the erase state ER. FIG. 10 is a diagram showing on a probabilistic-statistical basis in what voltage range the threshold voltage Vt of the large number of memory transistors MT1 and MT2 in the memory circuit 11 is distributed. The frequency reaches its maximum value at the intersection with the axis of the threshold voltage Vt. As shown in FIG. 10, the supply voltage VDD is lower than the minimum value Vt_min of the threshold voltage Vt in the erase state ER. This ensures that the threshold voltage Vt in the erase state ER is equal to or higher than the supply voltage VDD.

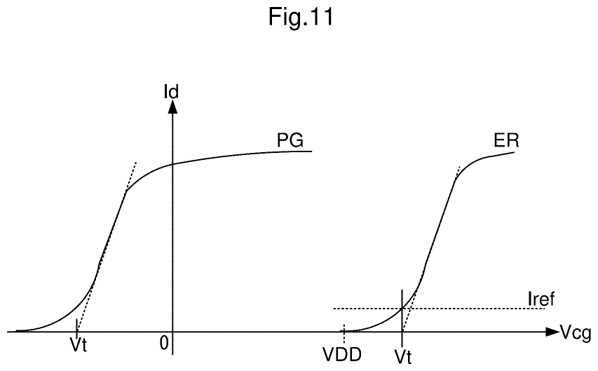

FIG. 11 shows the gate voltage Veg-drain current Id characteristics of the memory transistors MT1 and MT2. FIG. 11 shows the characteristics of the memory transistors MT1 and MT2 in the erase state ER and in the program state PG. As shown in FIG. 11, when the supply voltage VDD is fed as the gate voltage Veg, if the first memory transistor MT1 is in the erase state ER, the drain current Id is zero. If the first memory transistors MT1 in all the complementary cells CL are in the erase state, the current Isum1 is zero, so Isum1<Iref and, for example, the output of the amplifier 7 is at high level. In this state, if all the outputs (Vout [0] to Vout [31] in FIG. 9) of the plurality of amplifiers 7 are at high level, it is sensed that all the first memory cells MC1 in the memory circuit 11 are in the erase state. Providing an AND circuit that is fed with the outputs of the plurality of amplifiers 7 makes possible sensing based on one-bit data according to the output of the AND circuit.

By contrast, if even one of the first memory transistors MT1 in all the complementary cells CL is not in the erase state, the current Isum1>Iref and, for example, the output of the amplifier 7 is at low level.

As described above, by checking the logic output Vout it is possible to check whether all the first memory cells MC1 are in the erase state. A check for the erase state in the second memory cell MC2 is performed, as with the first memory cell MC1, by sensing the magnitude relationship between the current Isum2 flowing through the second bit lines BL2 etc. (i.e., the sum of the currents flowing through all the second memory cells MC2 connected to the second bit lines BL2 etc.) and the reference current Iref with the amplifier 7 that has selected the second bit lines BL2 etc. and checking the logic output Vout as the sensing result.

When all the first memory cells MC1 are checked to be in the erase state and all the second memory cells MC2 are checked to be in the erase state, all the complementary cells CL are checked to be in the delete state.

With this embodiment, the operation for the check for the erase state in all the complementary cells CL can be performed in two steps of operation, for the first bit lines and the second bit lines respectively, and this helps greatly reduce the time required for the check.

In this embodiment, the terminal 1A to be fed with the gate voltage Veg is fed with the supply voltage VDD fed to the terminal 1B. That is, for a purpose other than to feed the gate voltage Vcg, the supply voltage VDD (fed to the terminal 1B) necessary for the memory circuit 11 to operate is fed to the terminal 1A. The supply voltage VDD is generated within the IC chip 101, and this eliminates the need to provide the external terminal 10A as in the comparative example to the IC chip 101. While a single terminal can be shared as the terminals 1A and 1B, separating them permits the use of the configuration of the comparative example. The external terminal connected to the terminal 1A may be provided on the IC chip 101 and a direct-current voltage corresponding to the supply voltage VDD may be fed to the external terminal from the outside.

### 4. Second Embodiment of the Present Disclosure

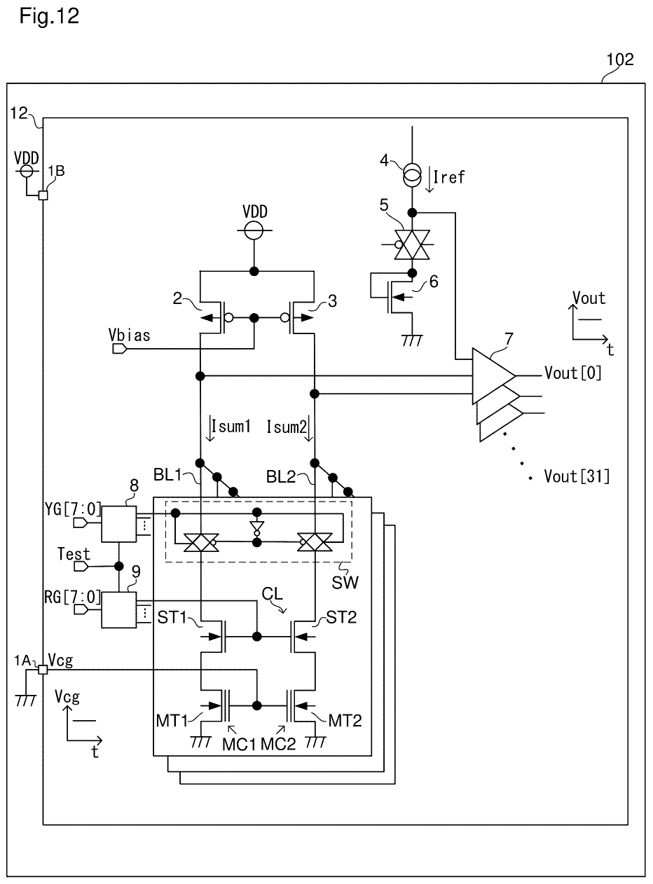

FIG. 12 is a schematic diagram showing an IC chip 102 having a memory circuit 12 according to a second embodiment of the present disclosure. The difference between this embodiment and the first embodiment is that the terminal 1A is fed with a ground potential (0 V).

In this embodiment, in the operation for the check for the erase state in the complementary cell CL, the ground potential is fed as the gate voltage Veg via the terminal 1A to the control gates of the memory transistors MT1 and MT2. Thus, as shown in FIG. 11, if the memory transistors MT1 and MT2 are in the erase state ER, the currents flowing through the memory cells MC1 and MC2 are zero. Accordingly, by sensing the magnitude relationship between the currents Isum1 and Isum2 and the reference current Iref with the amplifier 7 and checking the logic output Vout, it is possible to check all the complementary cells CL to be in the erase state.

In this embodiment, the terminal 1A is fed with the ground potential, so there is no need to provide the external terminal 10A as in the comparative example.

With the supply voltage VDD fed as the gate voltage Veg as in the first embodiment, the drain current tends to flow more easily, and this makes it easier to sense the memory transistors MT1 and MT2 being in an incomplete erase state (too small a shift of the threshold voltage Vt from 0 V). By contrast, feeding the ground potential as the gate voltage Veg as in the second embodiment helps relax the conditions for determining the erase state.

### 5. Others

The various technical features disclosed herein allow for any modifications made without departure from the spirit of the present disclosure. It should be understood that the above-described embodiments are in every aspect illustrative and not restrictive. The technical scope of the present disclosure is defined not by the description of the embodiments given above but by the appended claims, and encompasses any modifications made in a scope equivalent in significance to those claims.

### <6. Notes>

According to one aspect of what is disclosed herein, a memory circuit (11) includes:
a plurality of first bit lines (BL1) configured to be all connected together;
a plurality of second bit lines (BL2) configured to be all connect together;
a plurality of complementary cells (CL) having
   a first memory cell (MC1) connected to a first bit line and
   a second memory cell (MC2) connected to a second bit line;
a first switch (SW) provided for each pair of first and second bit lines and connected to the first and second memory cells;
a first all bit line selection circuit (8) operable, if an input test signal (Test) indicates a test, to turn on all the first switches regardless of the bit data of an input switch control signal (YG); and
a sensing circuit (7) configured to be operable to sense the magnitude relationship between the sum of currents flowing through the first bit lines (Isum1) and a reference current and the magnitude relationship between the sum of currents flowing through the second bit lines (Isum2) and the reference current,
wherein
the gate of a first memory transistor (MT1) included in the first memory cell and the gate of a second memory transistor (MT2) included in the second memory cell are operable to be fed with a direct-current voltage (VDD). (A first configuration.)

In the first configuration described above, the sensing circuit (7) may include a plurality of sensing circuits, and the first bit lines, the second bit lines, the complementary cells, the first switches, and the first all bit line selection circuit may be provided one each for each of the sensing circuits. (A second configuration.)

In the first or second configuration described above, the first memory cell (MC1) may have a first selection transistor (ST1) and the second memory cell (MC2) may have a second selection transistor (ST2). The memory circuit may include a second all bit line selection circuit (9) operable, if the input test signal indicates a test, to turn on all the pairs of first and second selection transistors regardless of the bit data of an input read gate signal (RG). (A third configuration.)

In any one of the first to third configurations described above, the direct-current voltage may be a first supply voltage (VDD). (A fourth configuration.)

In the fourth configuration described above, the first supply voltage (VDD) may be equal to a second supply voltage (VDD) necessary for the memory circuit (11) to operate for a purpose other than to feed the direct-current voltage to the gate. (A fifth configuration.)

The fifth configuration described above may further include a first terminal (1A) to be fed with the first supply voltage (VDD) and a second terminal (1B) to be fed with the second supply voltage (VDD). The first and second terminals may be separate terminals. (A sixth configuration.)

In any one of the first to third configurations described above, the direct-current voltage may be a ground potential. (A seventh configuration.)

According to another aspect of what is disclosed herein, an IC chip (101, 102) includes the memory circuit (11, 12) according to any one of the fifth to seventh configurations described above. (An eighth configuration.)

Any one of the first to seventh configurations described above may further include a second switch (5), a reference current source (4), and a diode-connected MOS transistor (6) connected to the reference current source via the second switch. (A ninth configuration.)

### INDUSTRIAL APPLICABILITY

The present disclosure finds applications in memory circuits for various uses.

### REFERENCE SIGNS LIST

1 memory circuit
1A, 1B terminal
2, 3 PMOS transistor
4 constant current source
5 switch
6 NMOS transistor
7 amplifier
8, 9 all bit line selection circuit
10 IC chip
10A external terminal
11, 12 memory circuit
101, 102 IC chip
BL bit line
BL1, BL3 first bit line
BL2, BL4 second bit line
CL complementary cell
Cg control gate
Fg floating gate
MC memory cell
MC1 first memory cell
MC2 second memory cell
MT memory transistor
MT1 first memory transistor
MT2 second memory transistor
Ox oxide film
PW P-well region
Rg read gate
SA sense amplifier
ST selection transistor
ST1 first selection transistor
ST2 second selection transistor
SW switch

1. A memory circuit comprising:
a plurality of first bit lines configured to be all connected together;
a plurality of second bit lines configured to be all connect together;
a plurality of complementary cells having
a first memory cell connected to a first bit line and
a second memory cell connected to a second bit line;
a first switch provided for each pair of first and second bit lines and connected to the first and second memory cells;
a first all bit line selection circuit operable, if an input test signal indicates a test, to turn on all the first switches regardless of bit data of an input switch control signal; and
a sensing circuit configured to be operable to sense a magnitude relationship between a sum of currents flowing through the first bit lines and a reference current and a magnitude relationship between a sum of currents flowing through the second bit lines and the reference current,
wherein
a gate of a first memory transistor included in the first memory cell and a gate of a second memory transistor included in the second memory cell are operable to be fed with a direct-current voltage.

2. The memory circuit according to claim 1, wherein
the sensing circuit includes a plurality of sensing circuits, and
the first bit lines, the second bit lines, the complementary cells, the first switches, and the first all bit line selection circuit are provided one each for each of the sensing circuits.

3. The memory circuit according to claim 1, wherein
the first memory cell has a first selection transistor;
the second memory cell has a second selection transistor; and
the memory circuit includes a second all bit line selection circuit operable, if the input test signal indicates a test, to turn on all the pairs of first and second selection transistors regardless of bit data of an input read gate signal.

4. The memory circuit according to claim 1, wherein
the direct-current voltage is a first supply voltage.

5. The memory circuit according to claim 4, wherein
the first supply voltage is equal to a second supply voltage necessary for the memory circuit to operate for a purpose other than to feed the direct-current voltage to the gate.

6. The memory circuit according to claim 5, further comprising:
a first terminal to be fed with the first supply voltage; and
a second terminal to be fed with the second supply voltage;
wherein
the first and second terminals are separate terminals.

7. The memory circuit according to claim 1, wherein
the direct-current voltage is a ground potential.

8. An IC chip comprising:
the memory circuit according to claim 1.

9. The memory circuit according to claim 1, further comprising:
a second switch;
a reference current source; and
a diode-connected MOS transistor connected to the reference current source via the second switch.
